(19) United States
(12) Patent Application Publication
(10) Pub. No.: US 2024/0045336 A1
(43) Pub. Date: Feb. 8, 2024

(54) METHOD FOR FORMING RESIST PATTERN BY USING EXTREME ULTRAVIOLET LIGHT AND METHOD FOR FORMING PATTERN BY USING THE RESIST PATTERN AS MASK

(71) Applicant: SAMSUNG ELECTRONICS CO., LTD., Suwon-si (KR)

(72) Inventors: Sookyung KIM, Suwon-si (KR); Chan HWANG, Suwon-si (KR); Jonghyun JUNG, Suwon-si (KR); Moosong LEE, Suwon-si (KR)

(21) Appl. No.: 18/133,118

(22) Filed: Apr. 11, 2023

(30) Foreign Application Priority Data
Aug. 4, 2022 (KR) 10-2022-0097412

(51) Int. Cl. G03F 7/20; G03F 7/004

(52) U.S. Cl. CPC G03F 7/2004; G03F 7/2022; G03F 7/0045

(57) ABSTRACT

A method for forming a resist pattern is disclosed. According to the method, a photosensitive layer is formed on a substrate by using an inorganic photoresist. The photosensitive layer is irradiated with a deep ultraviolet (DUV) light. The photosensitive layer is irradiated with an extreme ultraviolet (EUV) light after the irradiation of the DUV light. The photosensitive layer exposed to the EUV light is heated. The heated photosensitive layer is developed.

### CROSS-REFERENCE TO RELATED APPLICATION

This application claims priority under 35 USC § 119 to Korean Patent Application No. 10-2022-0097412, filed on Aug. 4, 2022, in the Korean Intellectual Property Office (KIPO), the entire disclosure of which is incorporated herein by reference.

### BACKGROUND

### 1. Field

Embodiments of the present disclosure relate to a method for forming a resist pattern. More particularly, embodiments of the present disclosure relate to a method for forming a resist pattern by using an extreme ultraviolet (EUV) light and a method for forming a pattern by using the resist pattern as a mask.

### 2. Description of the Related Art

As the degree of integration of semiconductor elements is improved and line widths of the semiconductor elements become finer, next-generation lithography technologies are being studied to improve the resolution of optical lithography. Among the next-generation lithography technologies, an extreme ultraviolet (EUV) light exposure scheme using an EUV light having a shorter wavelength than a deep ultraviolet (DUV) light as a light source is actively being developed.

### SUMMARY

According to exemplary embodiments, there is provided a method for forming a resist pattern. According to the method, a photosensitive layer is formed on a substrate by using an inorganic photoresist. The photosensitive layer is irradiated with a deep ultraviolet (DUV) light. The photosensitive layer is irradiated with an extreme ultraviolet (EUV) light after the irradiation of the DUV light. The photosensitive layer exposed to the EUV light is heated. The heated photosensitive layer is developed.

According to other exemplary embodiments, there is provided a method for forming a pattern. According to the method, a photosensitive layer is formed on a target layer by using an inorganic photoresist. The photosensitive layer is irradiated with a deep ultraviolet (DUV) light. The photosensitive layer is irradiated with an extreme ultraviolet (EUV) light the irradiation of the DUV light. The photosensitive layer exposed to the EUV light is heated. The heated photosensitive layer is developed to form a resist pattern; and etching the target layer by using the resist pattern as a mask.

According to yet other exemplary embodiments, a photosensitive layer including an inorganic photoresist may be exposed to a DUV light before being exposed to an EUV light. Therefore, the inorganic photoresist can be activated in advance, so that an EUV dose required for the exposure can be reduced. The reduction of the EUV dose can result in improvement of a speed of an entire exposure process. Therefore, efficiency of a process of manufacturing various elements and devices by using the exposure process can be improved.

### BRIEF DESCRIPTION OF THE DRAWINGS

Features will become apparent to those of skill in the art by describing in detail exemplary embodiments with reference to the attached drawings, in which:

FIG. 1 is a schematic view of a light-exposure system for forming a resist pattern according to an embodiment of the present disclosure.

FIGS. 2A, 2B, 2C, 2D, and 2E are cross-sectional views of stages in a method for forming a resist pattern according to an embodiment of the present disclosure.

FIG. 3 is a cross-sectional view of a method for forming a pattern according to an embodiment of the present disclosure.

FIG. 4 is a graph of an EUV dose of Comparative Example 1 and EUV doses measured through Examples 1 to 3.

### DETAILED DESCRIPTION

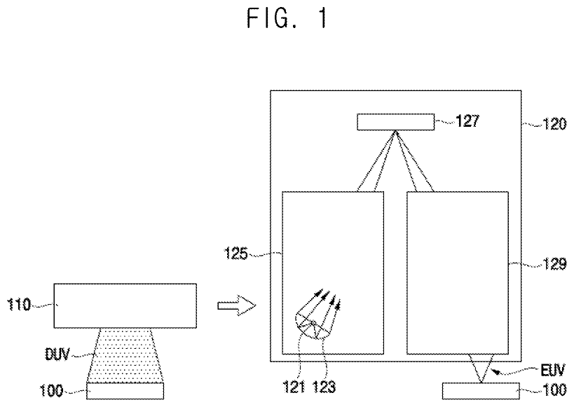

FIG. 1 is a view schematically showing a light-exposure system for forming a resist pattern according to an embodiment of the present disclosure.

Referring to FIG. 1, according to an embodiment of the present disclosure, a light-exposure system for forming a resist pattern may include a deep ultraviolet (DUV) exposure device 110 and an extreme ultraviolet (EUV) exposure device 120.

The DUV exposure device 110 may generate a DUV light to expose a substrate 100 to the DUV light. The substrate 100 may have a top surface coated with a photosensitive layer.

According to one embodiment, the DUV exposure device 110 may irradiate, e.g., simultaneously, an entire surface of the substrate 100 with the DUV light without using a mask. The exposure may be referred to as flood exposure.

The DUV exposure device 110 may include a DUV light source configured to generate a DUV light. The DUV light may have a wavelength in a range of 150 nm to 380 nm. For example, the DUV light source may include a lamp configured to generate a KrF laser (248 nm), an ArF laser (193 nm), an F₂ laser (157 nm), or the like.

According to one embodiment, the substrate 100 having the entire surface exposed to the DUV light may be, e.g., subsequently, selectively exposed to an EUV light according to a shape of the resist pattern to be formed. To perform the EUV exposure, the substrate 100 may be transferred to the EUV exposure device 120.

For example, the EUV exposure device 120 may include an EUV light source 121, a light-condensing member 123, a first optical system 125, an EUV mask 127, and a second optical system 129.

The EUV light source 121 may generate a light having a wavelength corresponding to the EUV light. For example, the EUV light may refer to an ultraviolet light having a wavelength in a range of 10 nm to 124 nm, e.g., a wavelength in a range of 13.0 nm to 14.0 nm or 13.4 nm to 13.6 nm. For example, the EUV light may have energy of 6.21 eV to 124 eV. However, embodiments of the present disclosure are not limited thereto, and the wavelength and the energy of the EUV light may vary depending on a photosensitive material to be exposed to a light, an optical system configured to transmit the EUV light, and the like.

The light-condensing member 123 may condense the EUV light generated by the EUV light source 121 to form a beam. The first optical system 125 may transmit the beam to the EUV mask 127. The beam may be filtered, e.g., by a monochromator or the like, to have a desired wavelength range before entering the first optical system 125.

The EUV mask 127 may include patterns having shapes to be transferred to the photosensitive layer of the substrate 100. The EUV light incident on the EUV mask may be reflected by the patterns, and the reflected EUV light may be projected onto the substrate 100 through the second optical system 129. For example, each of the first and second optical systems 125 and 129 may include a plurality of mirrors, and each of the mirrors may be a multilayer mirror.

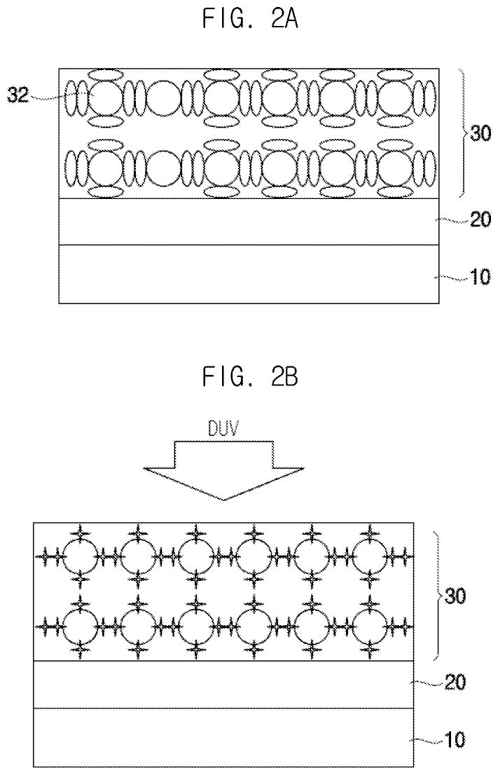

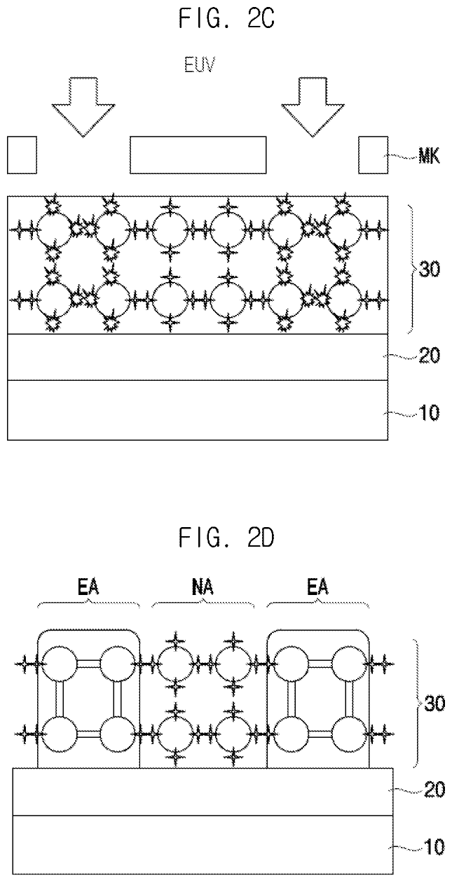

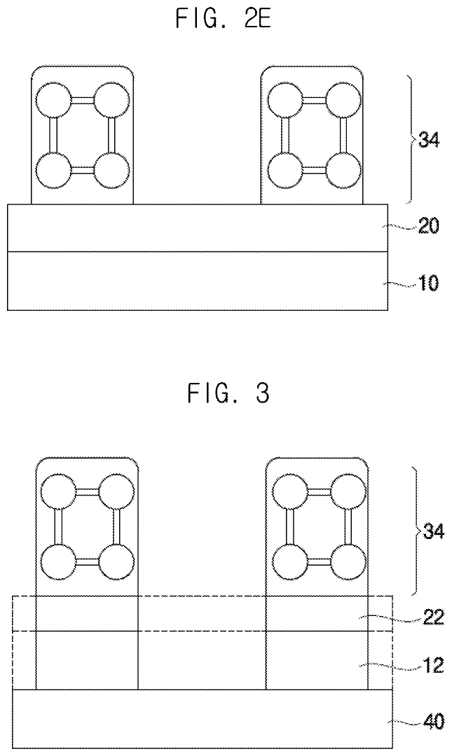

The light-exposure system may be used to expose the photosensitive layer to the DUV light and the EUV light in a method for forming a resist pattern that will be described below with reference to FIGS. 2A to 2E. FIGS. 2A, 2B, 2C, 2D, and 2E are cross-sectional views of stages in a method for forming a resist pattern according to an embodiment of the present disclosure.

Referring to FIG. 2A, a lower layer 20 and a photosensitive layer 30 may be formed on a target layer 10 of the substrate.

For example, the substrate may be a silicon wafer used for manufacturing a semiconductor device, a partially fabricated semiconductor device, a partially fabricated integrated circuit, or the like. The target layer 10 may include a semiconductor material, a conductive material, an insulating material, or a combination thereof. For example, the target layer 10 may be an etching target layer or a hardmask layer. In detail, the target layer 10 may include amorphous carbon, amorphous carbon doped with boron (B), amorphous carbon doped with tungsten (W), amorphous hydrogenated carbon, silicon oxide, silicon nitride, silicon oxynitride, silicon carbide, silicon boron nitride, amorphous silicon, polysilicon, or a combination thereof.

The lower layer 20 may be disposed between the target layer 10 and the photosensitive layer 30. The lower layer 20 may improve adhesion between the photosensitive layer 30 and the target layer 10. However, the embodiments of the present disclosure are not limited thereto, e.g., the photosensitive layer 30 may be formed directly on the target layer 10.

For example, the lower layer 20 may include a polymer material, and the target layer 10 may be coated with the lower layer 20 through spin coating or the like. In another example, the lower layer 20 may include an inorganic material. In yet another example, the lower layer 20 may include hydrated carbon, and the target layer 10 may be coated with the lower layer 20 including the hydrated carbon through vapor deposition. The hydrated carbon may be doped, e.g., with coral, silicon, nitrogen, halogen, boron, tungsten, or the like.

According to an embodiment, the photosensitive layer 30 may include an inorganic material. For example, the photosensitive layer 30 may include an inorganic photoresist based on a metal oxide. For example, the metal oxide may include tin, zinc, bismuth, antimony, or a combination thereof as a metal component. In addition, the metal oxide may include a metal oxide hydroxide.

The metal oxide may include an organic ligand bonded to a surface of metal oxide, e.g., to a metal atom. The ligands may be cleavable by the EUV light.

For example, the photosensitive layer 30 may include a metal oxide cluster 32. According to an embodiment, the photosensitive layer 30 may include a tin-oxo-cluster. The tin-oxo cluster may include an organic ligand bonded to tin, and some oxygen of the tin-oxo cluster may be hydrated to form a hydroxyl group (—OH).

Since the metal oxide cluster has a small molecular size, resolution of an exposure process may be improved. In addition, since an etching resistance is high, a thickness of the photosensitive layer may be reduced.

According to an embodiment, the photosensitive layer 30 may be formed by depositing a metal precursor, e.g., an organometallic precursor. For example, the photosensitive layer 30 may be formed by reacting Sn—Xₙ with a counter-reactant. In this case, X is a ligand, and may represent a dialkylamino group, e.g., a dimethylamino group, a methylethylamino group, or a diethylamino group, an alcohol, e.g., t-butoxy alcohol or isopropoxy alcohol, halogen, or other organic substituents.

For example, the organometallic precursor may include t-butyl-tris(dimethylamino)tin, i-butyl-tris(dimethylamino)tin, n-butyl-tris(dimethylamino)tin, sec-butyl-tris(dimethylamino)tin, i-propyl-tris(dimethylamino)tin, n-propyl-tris(dimethylamino)tin, t-butyl-tris(t-butoxy)tin, or a combination thereof.

For example, the counter-reactant may include oxygen (O₂), ozone (O₃), H₂O, hydrogen peroxide, oxygen plasma, H₂O plasma, alcohol, dihydroxy alcohol, polyhydroxy alcohol, fluorinated dihydroxy alcohol, fluorinated polyhydroxy alcohol, fluorinated glycol, formic acid, or a combination thereof.

If necessary, the organometallic precursor may be heat-treated or calcined after being deposited.

For example, the photosensitive layer 30 including the metal oxide cluster 32 may be formed by coating a liquid composition including the metal oxide cluster. For example, the photosensitive layer 30 may be formed by spin-coating the substrate with the liquid composition.

The liquid composition including the metal oxide cluster may further include a suitable solvent. For example, the solvent may include methanol, ethanol, propanol, isopropanol, butanol, t-butyl alcohol, methoxyethanol, ethoxyethanol, acetylacetone, formamide, dimethylformamide, N-methylformamide, dimethyl sulfoxide, ethanolamine, or a combination thereof.

If necessary, pre-baking may be performed before exposing the photosensitive layer 30 to a light. For example, the pre-baking may be performed at 50° C. to 150° C., e.g., 80° C. to 120° C. Through the pre-baking, the solvent within the photosensitive layer 30 may be removed or reduced, and exposure sensitivity of the photosensitive layer may be improved.

The pre-baking may be performed in a vacuum or gas atmosphere. The gas atmosphere may include, e.g., air, H₂, CO₂, O₂, N₂, Ar, He, or a mixture thereof.

For example, the photosensitive layer 30 may have a thickness of 100 nm or less, e.g., a thickness of 50 nm or less. For example, the photosensitive layer 30 may have a thickness of 10 nm to 30 nm.

Referring to FIG. 2B, the photosensitive layer 30 may be irradiated with the DUV light. According to an embodiment, an entire surface of the photosensitive layer may be irradiated with the DUV light. Therefore, the photosensitive layer 30 may be exposed to the light without a mask.

Referring to FIG. 2C, the photosensitive layer 30 having the entire surface exposed to the DUV light may be irradiated with the EUV light. A partial area of the photosensitive layer 30 may be selectively irradiated with the EUV light. The exposure area may be determined according to a shape of a mask MK, e.g., the EUV light may be irradiated only on portions of the photosensitive layer 30 that are exposed (open) by the mask MK. For example, when viewed in a plan view, the exposure area may have various shapes, e.g., a grid shape, a stripe shape, a polygonal shape, a circular shape, and an elliptical shape, and a plurality of adjacent exposure areas may be connected to or separated from each other. Although the mask MK has been shown in FIG. 2C as having a light-transmitting area corresponding to the exposure area, the above configuration has been provided for illustrative purposes for description, and a shape of the exposure area may also be determined by a reflection pattern of the EUV mask 127 shown in FIG. 1.

Upon the exposure to the EUV light, the organic ligand of the inorganic photoresist (metal oxide cluster) may be removed from a metal, and a metal-hydrogen bond (e.g., Sn—H) may be formed.

Referring to FIG. 2D, the photosensitive layer 30 exposed to the EUV light may be heat-treated (post-exposure bake). An Sn—H bond formed in the EUV exposure process may be thermally activated so that crosslinking reaction of adjacent clusters may occur. For example, Sn—H may react with Sn—OH in an adjacent cluster to form an Sn—O—Sn bond or an Sn—Sn bond. Accordingly, a network structure of SnOₓ may be formed in the exposure area EA exposed to the EUV light. Accordingly, a difference in characteristics (etch-resistances) between the exposure area EA and a non-exposure area NA with respect to a developer may be increased.

According to an embodiment, the heat treatment may be performed at a higher temperature than a heat treatment before the exposure. For example, the heat treatment may be performed at 150° C. to 250° C., e.g., at 160° C. to 180° C. When a temperature of the heat treatment is excessively low, the crosslinking reaction for forming the network structure may not occur sufficiently. Accordingly, an etching resistance of the exposure area EA may be decreased, or a difference in etching characteristics between the exposure area EA and the non-exposure area NA may be reduced. When the temperature of the heat treatment is excessively high, uniformity of the pattern may deteriorate.

The heat treatment after the exposure may be performed in a vacuum or gas atmosphere. The gas atmosphere may include, e.g., air, H₂, CO₂, O₂, N₂, Ar, He, or a mixture thereof.

Referring to FIG. 2E, the photosensitive layer may be partially removed by applying a developer to the photosensitive layer exposed to the light, so that a resist pattern 34 may be formed. According to one embodiment, the resist pattern 34 may be formed by removing the non-exposure area NA and allowing the exposure area EA to remain. However, the embodiments of the present disclosure are not limited thereto, and depending on materials of the developer and the resist, the exposure area EA may be removed while the non-exposure area NA remains.

For example, a negative-tone developer for removing the non-exposure area NA may include halogen acid, e.g., HCl or HBr, organic acid, e.g., formic acid, acetic acid, or citric acid, and an organic fluorine compound, e.g., trifluoroacetic acid, and the halogen acid, organic acid, and the organic fluorine compound may be used together with water or an organic solvent. In addition, an organic developer, e.g., 2-heptanone, isopropyl alcohol (IPA), propylene glycol methyl ether (PGME), or propylene glycol methyl ether acetate (PGMEA) may be used as the negative-tone developer.

For example, a positive-tone developer may include ammonium hydroxide (NH₄OH), tetramethylammonium hydroxide (TMAH), tetraethylammonium hydroxide (TEAH), tetrapropylammonium hydroxide (TPAH), tetrabutylammonium hydroxide (TBAH), and the like.

However, the embodiments of the present disclosure are not limited to wet development described above, and the photosensitive layer may be patterned through dry development.

If necessary, after the development, a heat treatment may be performed to improve characteristics of the resist pattern 34. The heat treatment after the development may be performed in a vacuum or gas atmosphere. The gas atmosphere may include, e.g., air, H₂, CO₂, O₂, N₂, Ar, He, or a mixture thereof.

According to an embodiment, the heat treatment after the development may use plasma. A plasma treatment may increase hardness of the resist pattern, which may increase characteristics of the resist pattern as a mask.

According to an embodiment, the photosensitive layer including the inorganic photoresist may be exposed to the DUV light before being exposed to the EUV light. Therefore, the inorganic photoresist may be activated in advance, so that an EUV dose required for the exposure may be reduced. The reduction of the EUV dose may result in improvement of a speed of the entire exposure process. Therefore, efficiency of the process of manufacturing various elements and devices by using the exposure process may be improved.

According to an embodiment, the inorganic photoresist may have a DUV light absorption rate that is lower than an EUV light absorption rate. For example, the inorganic photoresist may have a DUV light absorption constant (k) that is lower than an EUV light absorption constant. When the DUV light absorption rate of the inorganic photoresist is excessively high, the difference in the etching characteristics between the exposure area and the non-exposure area may be reduced. For example, when the EUV light has a wavelength of about 13.5 nm (13 nm to 14 nm), an EUV light absorption constant of the inorganic photoresist may be about 0.147, and a KrF laser that generates a light having a wavelength of about 248 nm (245 nm to 250 nm) in which an absorption constant of the inorganic photoresist is about 0.071 may be used as a DUV light source. According to the embodiments of the present disclosure, as a DUV dose

increases, the EUV dose may be reduced. For example, 1 mJ/cm² of KrF may reduce the EUV dose by about 2 mJ/cm².

According to an embodiment, a ratio of doses of the EUV light and the DUV light may be 50:1 to 3:1, e.g., 20:1 to 4:1. For example, the EUV dose may be 120 mJ/cm² to 190 mJ/cm², e.g., 120 mJ/cm² to 180 mJ/cm², and the DUV dose may be 5 mJ/cm² to 40 mJ/cm², e.g., 10 mJ/cm² to 35 mJ/cm². However, the embodiments of the present disclosure are not limited thereto, and the EUV and DUV doses may vary depending on a line width, a pitch, and the like of the pattern. When the DUV dose is excessively small, it may be difficult to sufficiently reduce the EUV dose, and when the DUV dose is excessively large, the difference in the etching characteristics between the exposure area and the non-exposure area may be reduced.

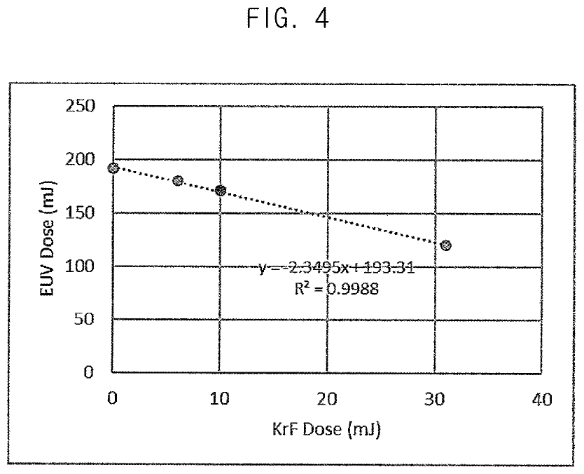

FIG. 3 is a cross-sectional view of a method for forming a pattern according to one embodiment of the present disclosure.

Referring to FIGS. 2E and 3, a target pattern 12 may be formed by etching the target layer 10 by using the resist pattern 34 formed in FIG. 2E as a mask. The target pattern 12 may have a shape corresponding to the resist pattern 34.

In order to etch the target layer 10, the lower layer 20 may be etched first to form a lower layer pattern 22. The target layer 10 and the lower layer 20 may be etched by the same etchant, or may be etched by mutually different etchants.

For example, the lower layer 20 and the target layer 10 may be dry-etched. For example, the lower layer 20 and the target layer 10 may be etched by plasma, reactive ions, or the like. However, the embodiments of the present disclosure are not limited thereto. For example, the lower layer 20 and the target layer 10 may be etched by mutually different etchants, or at least one of the lower layer 20 and the target layer 10 may be wet-etched.

In addition, when the target pattern 12 is a hardmask, a lower structure 40 disposed under the target pattern 12 may be further etched by using the target pattern 12 as a mask.

If necessary, the resist pattern 34 may be removed. For example, the resist pattern 34 may be removed through dry etching, removed through wet etching, or peeled through removal of the lower layer 20.

Hereinafter, effects of the embodiments of the present disclosure will be explained with reference to experiments.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Comparative Example 1

A silicon wafer was coated with an inorganic photoresist composition including a tin oxide cluster to form a photosensitive layer having a thickness of about 30 nm. The photosensitive layer was exposed to an EUV light (dose: 192 mJ/cm²) to transfer a circular array pattern (pitch: 32 nm). The photosensitive layer exposed to the EUV light was heat-treated at about 170° C. for 60 seconds, and developed by using a negative-tone developer to form a circular pillar array.

### Example 1

A silicon wafer was coated with an inorganic photoresist composition including a tin oxide cluster to form a photosensitive layer having a thickness of about 30 nm. An entire surface of the photosensitive layer was exposed to a KrF laser (dose: 6 mJ/cm²), and subsequently exposed to an EUV light to transfer a circular array pattern (pitch: 32 nm). The photosensitive layer exposed to the EUV light was heat-treated at about 170° C. for 60 seconds, and developed by using a negative-tone developer to form a circular pillar array.

### Example 2

A circular pillar array was formed in the same manner as in Example 1, except that the dose of the KrF laser for the exposure was 10 mJ/cm².

### Example 3

A circular pillar array was formed in the same manner as in Example 1, except that the dose of the KrF laser for the exposure was 30 mJ/cm².

In Examples 1 to 3, EUV doses required to form the same pattern as in Comparative Example 1 was measured. FIG. 4 is a graph showing an EUV dose of Comparative Example 1 and EUV doses measured through Examples 1 to 3.

Referring to FIG. 4, it can be noted that as the dose of the KrF laser for the exposure increases, the EUV dose required is decreased, and 1 mJ/cm² of KrF may reduce the EUV dose by about 2 mJ/cm².

By way of summation and review, embodiments provide a method for forming a resist pattern, which uses an EUV light as a light source, and has improved productivity. Embodiments also provide a method for forming a pattern by using the resist pattern as a mask.

That is, according to embodiments, a photosensitive layer including an inorganic photoresist is exposed to DUV, before exposure to EUV, in order to increase efficiency of a lithography process using EUV. Thus, the inorganic photoresist can be activated in advance (i.e., by the DUV), so that the EUV dose required for the lithography process may be reduced, thereby increasing a speed of a whole exposure process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method for forming a resist pattern, the method comprising:
forming a photosensitive layer on a substrate by using an inorganic photoresist;
irradiating the photosensitive layer with a deep ultraviolet (DUV) light;
irradiating the photosensitive layer with an extreme ultraviolet (EUV) light, after irradiating with the DUV light;
heating the photosensitive layer, after irradiating with the EUV light; and
developing the heated photosensitive layer.

2. The method as claimed in claim 1, wherein the inorganic photoresist includes a metal oxide.

3. The method as claimed in claim 2, wherein the metal oxide has an organic ligand bonded to a metal atom.

4. The method as claimed in claim 3, wherein oxygen of the metal oxide is partially hydrated to form a hydroxyl group (—OH).

5. The method as claimed in claim 1, wherein the inorganic photoresist includes a tin-oxo-cluster.

6. The method as claimed in claim 5, wherein the inorganic photoresist has a DUV light absorption rate that is lower than an EUV light absorption rate.

7. The method as claimed in claim 6, wherein the EUV light has a wavelength in a range of 13 nm to 14 nm, and the DUV light has a wavelength in a range of 245 nm to 250 nm.

8. The method as claimed in claim 7, wherein the DUV light is generated by a KrF laser.

9. The method as claimed in claim 1, wherein the DUV light has a wavelength in a range of 150 nm to 380 nm.

10. The method as claimed in claim 1, wherein a ratio of doses of the EUV light and the DUV light is 20:1 to 4:1.

11. The method as claimed in claim 1, wherein:
irradiating the photosensitive layer with the DUV light includes irradiating an entire surface of the photosensitive layer with the DUV light, and
irradiating the photosensitive layer with the EUV light includes irradiating the photosensitive layer only partially with the EUV light.

12. The method as claimed in claim 11, wherein, when the heated photosensitive layer is developed, an area of the photosensitive layer, which is not irradiated with the EUV light, is removed.

13. The method as claimed in claim 1, wherein the photosensitive layer irradiated with the EUV light is heated at 150° C. to 250° C.

14. A method for forming a pattern, the method comprising:
forming a photosensitive layer on a target layer by using an inorganic photoresist;
irradiating the photosensitive layer with a deep ultraviolet (DUV) light;
irradiating the photosensitive layer with an extreme ultraviolet (EUV) light, after irradiating with the DUV light;
heating the photosensitive layer, after irradiating with the EUV light;
developing the heated photosensitive layer to form a resist pattern; and
etching the target layer by using the resist pattern as a mask.

15. The method as claimed in claim 14, wherein the inorganic photoresist includes a metal oxide.

16. The method as claimed in claim 15, wherein the inorganic photoresist has a DUV light absorption rate that is lower than an EUV light absorption rate.

17. The method as claimed in claim 16, wherein the EUV light has a wavelength in a range of 13 nm to 14 nm, and the DUV light has a wavelength in a range of 245 nm to 250 nm.

18. The method as claimed in claim 17, wherein the DUV light is generated by a KrF laser.

19. The method as claimed in claim 14, wherein a ratio of doses of the EUV light and the DUV light is 20:1 to 4:1.

20. The method as claimed in claim 14, wherein the photosensitive layer exposed to the EUV light is heated at 150° C. to 250° C.
